(19) United States
(12) Patent Application Publication
(10) Pub. No.: US 2009/0020884 A1
(43) Pub. Date: Jan. 22, 2009

(54) SURFACE TREATMENT METHOD, SEMICONDUCTOR DEVICE AND METHOD OF FORMING THE SEMICONDUCTOR DEVICE

(75) Inventors: Hun-Hee LEE, Gyeonggi-do (KR); Min-Sang YUN, Gyeonggi-do (KR); Hee-Chan JUNG, Gyeonggi-do (KR); Seung-Kyung AHN, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/176,226

(22) Filed: Jul. 18, 2008

(30) Foreign Application Priority Data
Jul. 19, 2007 (KR) 2007-72333

(51) Int. Cl. H01L 21/768; H01L 23/522

(52) U.S. Cl. 257/774; 438/675; 257/E21.585; 257/E23.145

(57) ABSTRACT

Provided are methods of surface treatment, semiconductor devices and methods of forming the semiconductor device. The methods of forming the semiconductor device include forming a first oxide layer and a second oxide layer on a substrate. The first and second oxide layers are patterned to form a contact hole exposing the substrate. A sidewall of the first oxide layer exposed by the contact hole reacts with HF to form a first reaction layer and a sidewall of the second oxide layer exposed by the contact hole reacts with NH₃ and HF to form a second reaction layer. The first and second reaction layers are removed to enlarge the contact hole. A contact plug is formed in the enlarged contact hole.

### CROSS-REFERENCE TO RELATED APPLICATIONS

This U.S. non-provisional patent application claims priority under 35 U.S.C. § 119 of Korean Patent Application No. 2007-72333, filed on Jul. 19, 2007, the entire contents of which are hereby incorporated by reference.

### BACKGROUND OF THE INVENTION

The present invention disclosed herein relates to semiconductor devices, and more particularly, to a surface treatment method, a semiconductor device and a method of forming the semiconductor device using the surface treatment method.

Semiconductor devices are generally formed by repeatedly performing a thin film process, a photo process, an etching process and a cleaning process. After any one process is performed, the cleaning process may be performed in order to remove oxide material which remains on a semiconductor surface before next process is performed. Conventionally, a wet process using a thin hydro fluoric acid solution was used to remove the oxide material which remains on the semiconductor surface. However, since a thin hydro fluoric acid solution used in a wet process generates particles on a substrate surface and also damages other layers, a dry process such as a chemical oxide removal (COR) is introduced. However, the introduced dry process can not effectively remove oxide material which remains in a contact hole or at least two kinds of oxide materials.

In the meantime, a semiconductor device is formed by stacking conductive layers and insulating layers. A contact plug which penetrates an insulating layer is formed to electrically connect the conductive layers to each other. As a semiconductor device is highly integrated, various difficulties occur in forming the contact plug. It is desirable that a size of a contact plug increases to reduce an electric resistance or to prevent misalign, but it goes against a high integration. Though a contact plug is formed under a given design rule, it is electrically connected to an adjacent conductive layer. As a result, reliability and an operational characteristic of a semiconductor device may be degraded.

### SUMMARY OF THE INVENTION

Example embodiments provide a surface treatment method of removing oxide material on a surface of a substrate. The method may include reacting the oxide material with HF to form a reaction layer and heating and removing the reaction layer.

Example embodiments provide a surface treatment method of removing a first oxide material and a second oxide material on a surface of a substrate. The method may include reacting the first oxide material with HF to form a first reaction layer, reacting the second oxide material with HF and NH₃ to form a second reaction layer, and removing the first and second reaction layers.

Example embodiments provide a method of forming a semiconductor device. The method may include forming a first oxide layer and a second oxide layer on a substrate, patterning the first and second oxide layers to form a contact hole that exposes the substrate, reacting a sidewall of the first oxide layer exposed by the contact hole with HF to form a first reaction layer, reacting a sidewall of the second oxide layer exposed by the contact hole with NH₃ and HF to form a second reaction layer, removing the first and second reaction layers to enlarge the contact hole, and forming a contact plug in the enlarged contact hole.

Example embodiments provide a method of forming a semiconductor device. The method may include forming a first interlayer insulating layer including a conductive pad connected to an active region on a substrate including the active region, forming a second interlayer insulating layer and a third interlayer insulating layer on the first interlayer insulating layer, patterning the second and third interlayer insulating layers to form a contact hole exposing the conductive pad, reacting a sidewall of the second interlayer insulating layer exposed by the contact hole with HF to form a first reaction layer, reacting a sidewall of the third interlayer insulating layer exposed by the contact hole with NH3 and HF to form a second reaction layer, removing the first and second reaction layers to enlarge the contact hole, and forming a contact plug in the enlarged contact hole.

Example embodiments provide semiconductor device. The device may include a first oxide layer on a substrate, a second oxide layer on the first oxide layer, and a contact plug that penetrates the first and second oxide layers and is connected to the substrate, the contact plug including a first portion and a second portion which have different widths.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIGS. 1 to 3 are cross sectional views of a semiconductor device illustrating an embodiment of a surface treatment method in accordance with the present invention.

FIGS. 4 to 7 are cross sectional views of a semiconductor device illustrating another embodiment of a surface treatment method in accordance with the present invention.

FIGS. 8 to 12 are cross sectional views of a semiconductor device illustrating an embodiment of the semiconductor device and a method of forming the semiconductor device in accordance with the present invention.

FIGS. 13A to 19A are top plan views illustrating another embodiment of a semiconductor device and a method of forming the semiconductor device in accordance with the present invention and FIGS. 13B to 19B are cross sectional views taken along the lines I-I′ and II-II′ of FIGS. 13A to 19A.

FIGS. 20 to 25 are cross sectional views of a semiconductor device illustrating still another embodiment of the semiconductor device and a method of forming the semiconductor device in accordance with the present invention.

FIGS. 26A and 26B represent reaction gases used in some embodiments of the present invention and the amount of material chemically removed by the reaction gases.

FIG. 27 is a flow chart illustrating a method of forming a semiconductor device in accordance with some embodiments of the present invention.

FIG. 28 represents a process step recipe illustrating a method of forming a semiconductor device in accordance with some embodiments of the present invention.

### DETAILED DESCRIPTION OF PREFERRED EMBODIMENTS

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

In the drawings, the thickness of layers and regions are exaggerated for clarity. It will also be understood that when an element such as a layer, region or substrate is referred to as being “on” or “onto” another element, it may lie directly on the other element or intervening elements or layers may also be present. Like reference numerals refer to like elements throughout the specification.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first region/layer could be termed a second region/layer, and, similarly, a second region/layer could be termed a first region/layer without departing from the teachings of the disclosure.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Embodiments of the present invention may be described with reference to cross-sectional illustrations, which are schematic illustrations of idealized embodiments of the present invention. As such, variations from the shapes of the illustrations, as a result, for example, of manufacturing techniques and/or tolerances, are to be expected. Thus, embodiments of the present invention should not be construed as limited to the particular shapes of regions illustrated herein, but are to include deviations in shapes that result from, e.g., manufacturing. For example, a region illustrated as a rectangle may have rounded or curved features. Thus, the regions illustrated in the figures are schematic in nature and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

Spatially relatively terms, such as “beneath,” “below,” “above,” “upper,” “top,” “bottom” and the like, may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, when the device in the figures is turned over, elements described as below and/or beneath other elements or features would then be oriented (rotated 90 degrees or at other orientations) and the spatially relative descriptors used herein interpreted accordingly. As used herein, “height” refers to a direction that is generally orthogonal to the faces of a substrate.

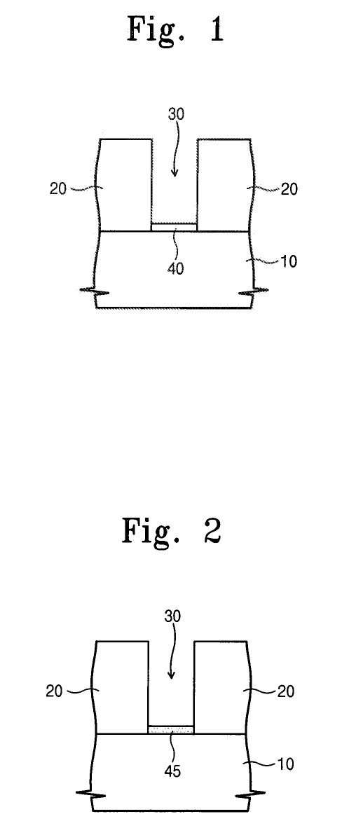

Referring to FIGS. 1 to 3, an embodiment of a surface treatment method in accordance with the present invention is described.

Referring to FIG. 1, an insulating layer 20 is formed on a substrate 10. The insulating layer 20 may be a multi-layer structure including at least two oxide layers. The insulating layer 20 is patterned to form a contact hole 30 exposing the substrate 10. Oxide material 40 may remain on the substrate 10 in the contact hole. The oxide material 40 may be boron phosphor silicate glass (BPSG).

Referring to FIG. 2, a process gas is provided to the substrate 10. The process gas may include a reaction gas and an unreacted gas. The reaction gas may include HF. For example, the reaction gas may be formed of only HF gas. An unreacted gas may include nitrogen and/or an inactivated gas (e.g., argon Ar). The reaction gas is reacted to the oxide material 40 to form a reaction layer 45 and the unreacted gas maintains or controls a pressure (hereinafter, it is referred to as a process pressure) of a process chamber (not shown) including the substrate 10 or is used as a purge gas. The reaction gas and the unreacted gas may be simultaneously or sequentially provided. The reaction gas and the unreacted gas may also be repeatedly provided.

As shown in a below reaction formula, the provided reaction gas HF is reacted to the oxide material 40 to form the reaction layer 45 including SiF₄.

SiO₂+4HF→SiF₄+2H₂O [reaction formula 1]

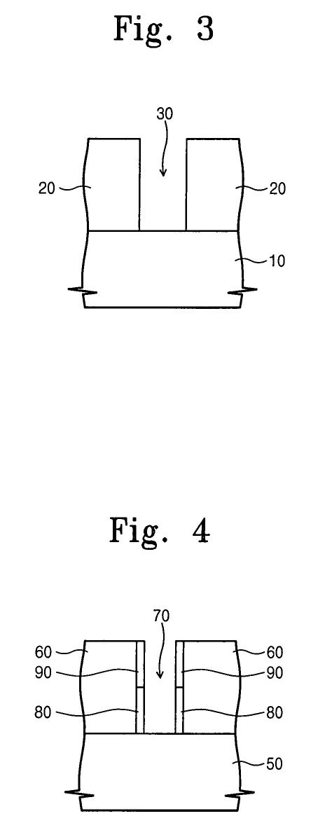

Referring to FIG. 3, the reaction layer 45 is evaporated and removed by heating the substrate 10. A heating temperature may be 100˜200° C. The substrate 10 may be heated using various methods. For example, the heating may be performed by a heater equipped in a chuck (not shown) where the substrate 10 is put.

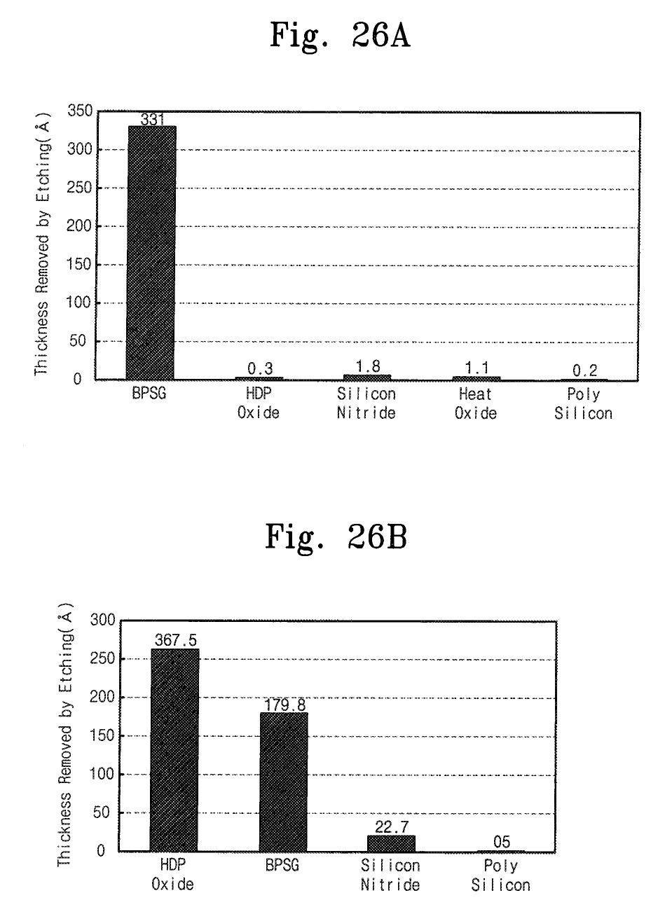

FIG. 26A represents HF used as a reaction gas in the above embodiment and the amount of material chemically removed by the HF. Here, the amount of removed material means a thickness of removed material. FIG. 26A represents the removed amount in a case that the HF and the unreacted gas are provided at flow rates of 90 sccm and 500 sccm, respectively under a process pressure of 200 mT for 60 seconds. Referring to FIG. 26A, when the amount of removed BPSG is 331 Å, a high density plasma (HDP) oxide material, silicon oxide material, silicon nitride, thermal oxide material and polysilicon are etched by a thickness of 0.3 Å, a thickness of 1.8 Å, a thickness of 1.1 Å, and a thickness of 0.2 Å, respectively. If HF is used as an reaction gas, the amount of removed BPSG is 1103 times, 184 times, 301 times, and 1655 times as large as the amount of removed HDP oxide material, silicon nitride, thermal oxide material and polysilicon, respectively. BPSG may be selectively removed with respect to HDP oxide material, thermal oxide material, silicon nitride, polysilicon by using HF as a reaction gas. Referring to FIG. 3 again, the reaction layer 45 may be removed without damages of the substrate 10 and the insulating layer 20. The oxide material 40 in the contact hole 30 may be removed without damages of the substrate 10 and the insulating layer 20.

Referring to FIGS. 4 to 7, another embodiment of a surface treatment method will be described.

Referring to FIG. 4, an insulating layer 60 is formed on a substrate 50. The insulating layer 60 may be a multi-layer structure including at least two oxide layers. The insulating layer 60 is patterned to form a contact hole 70 exposing the substrate 50. A first oxide material 80 and a second oxide material 90 may remain on a sidewall of the insulating layer 60 in the contact hole 70. For example, the first oxide material 80 may be BPSG and the second oxide material 90 may be high density plasma (HDP) or tetra ethyl ortho silicate).

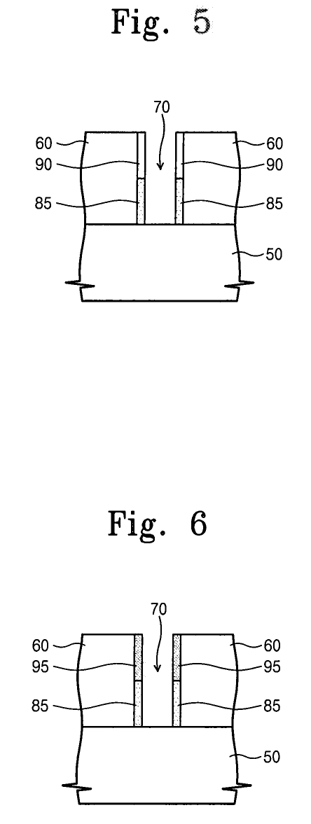

Referring to FIG. 5, a first process gas is provided to the substrate 50. The first process gas may include a first reaction gas and an unreacted gas. The first reaction gas may include HF. For example, the first reaction gas may include only HF. The unreacted gas may include nitride and/or an inactivated gas (e.g., an argon gas). The first reaction gas is reacted to the first oxide material 80 to form a first reaction layer 85 and the unreacted gas maintains or controls a pressure of a process chamber (not shown) including the substrate 50 or is used as a purge gas. The first reaction gas and the unreacted gas may be simultaneously or sequentially provided. The first reaction gas and the unreacted gas may also be repeatedly provided.

As shown in the above first reaction formula, the provided first reaction gas HF is reacted to the first oxide material 80 to form the reaction layer 85 including SiF₄.

Referring to FIG. 6, a second process gas is provided to the substrate 50. The second process gas may include a second reaction gas and an unreacted gas. The second reaction gas may include HF or NH₃. The unreacted gas may include nitride and/or an inactivated gas (e.g., an argon gas). The second reaction gas is reacted to the second oxide material 90 to form a second reaction layer 95 and the unreacted gas maintains or controls a pressure of a process chamber (not shown) including the substrate 50 or is used as a purge gas. The second reaction gas and the unreacted gas may be simultaneously or sequentially provided. The second reaction gas and the unreacted gas may also be repeatedly provided.

As shown in the above first reaction formula, and below second and third reaction formulas, the provided second reaction gas NH₃ and HF is reacted to the second oxide material 90 to form the second reaction layer 95 including SiF₄ and/or (NH₄)₂SiF₆. A portion of the second reaction gas may react to the first reaction layer.

SiO₂+4HF+4NH₃→SiF₄+2H₂O+4NH₃ [reaction formula 2]

SiF₄+2HF+2NH₃(NH₄)₂SiF₆ [reaction formula 3]

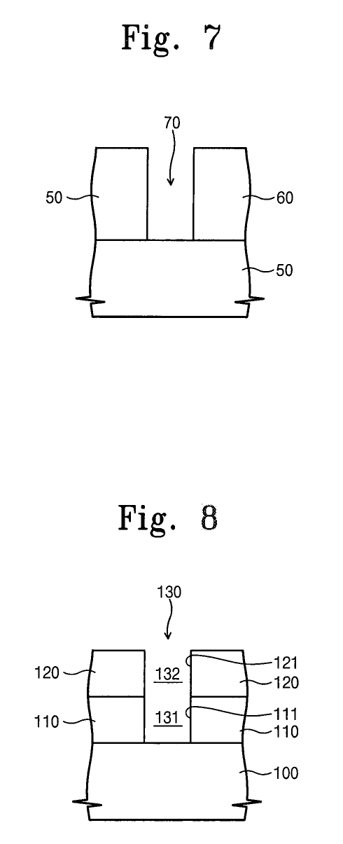

Referring to FIG. 7, the first reaction layer 85 and the second reaction layer 95 are evaporated and removed by heating the substrate 50. A heating temperature may be 100˜200° C. The substrate 50 may be heated using various methods. For example, the heating may be performed by a heater equipped in a chuck (not shown) where the substrate 50 is put.

Described parts in aforementioned embodiment with reference to FIG. 26A may be identically applied to the present embodiment. BPSG may selectively be removed with respect to HDP oxide material, thermal oxide material, silicon nitride, polysilicon by using HF as the first reaction gas in the present embodiment.

FIG. 26B represents NH₃ and HF used as the second reaction gas in the above embodiment and the amount of material chemically removed by the NH₃ and HF. Here, the amount of removed material means a thickness of removed material. FIG. 26B represents the removed amount in a case that NH₃, HF and an unreacted gas are provided at flow rates of 40 sccm, 40 sccm and 100 sccm, respectively under a process pressure of 80 mT for 90 seconds. Referring to FIG. 26B, when the amount of removed HDP oxide material is 267.5 Å, BPSG, silicon nitride, and polysilicon are etched by a thickness of 179.8 Å, a thickness of 22.7 Å, and a thickness of 0.05 Å, respectively. If NH₃ and HF are used as an reaction gas, the amount of removed HDP oxide material is 1.49 times, 11.78 times, and 5350 times as large as the amount of removed HDP oxide material, silicon nitride, thermal oxide material and polysilicon, respectively. HDP oxide material or tetra ethyl ortho silicate (TEOS) may be selectively removed with respect to silicon nitride, polysilicon by using NH₃ and HF as a reaction gas. The BPSG 80 and the HDP oxide material 90 (or TEOS) in the contact hole 70 are selectively reacted to the respective first and second reaction gases and become a first reaction layer 85 and a second reaction layer 95. The first and second reaction layers 85 and 95 are simultaneously removed by heating. Though the first and second reaction layers 85 and 95 are formed by performing two separated processes, productivity is not degraded because the two separated processes correspond to in-situ process. Referring to FIG. 7 again, the first and second reaction layers 85 and 95 are removed without damages of the substrate 50 and the insulating layer 60. That is, the first oxide material 80 and the second oxide material 90 in the contact hole 70 are clearly removed without damages of the substrate 50 and the insulating layer 60. Thus, a surface treatment method in accordance with some embodiments of the present invention may prevent some problems such as a malfunction of a device, a reduction of lifetime, and a degradation of an operational characteristic which may occur by oxide material which remain on a surface of the substrate, in particular, in a contact hole.

Referring to FIGS. 8 to 12 and FIG. 27, an embodiment of a semiconductor device and a method of forming the same according to the present invention.

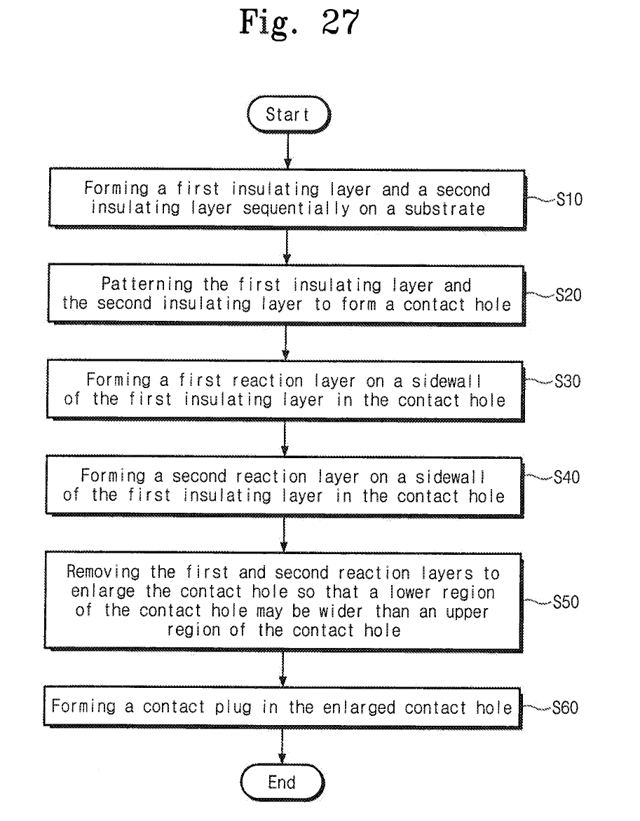

Referring to FIGS. 8 and 27, a first insulating layer 110 and a second insulating layer 120 are sequentially formed on a substrate 100 (S10). The first and second insulating layers 110 and 120 may be formed using a chemical vapor deposition (CVD) process. For example, the first insulating layer 110 may be formed of BPSG and the second insulating layer 120 may be formed of HDP oxide material or TEOS.

The first and second insulating layers 110 and 120 are patterned to form a contact hole 130 exposing the substrate 100 (S20). The contact hole 130 may include a lower region 131 and an upper region 132. The lower region 131 may have substantially the same width as the upper region 132. That is, the contact hole 130 may have a uniform width. Sidewalls 111 and 121 of the first and second insulating layers 110 and 120 patterned by the contact hole 130 are exposed. The exposed sidewalls of the patterned first and second insulating layers 110 and 120 limit the contact hole 130. The sidewall 111 of the first insulating layer 110 limits the lower region 131 of the contact hole 130 and the sidewall 121 of the second insulating layer 120 limits the upper region 121 of the contact hole 130.

Referring to FIGS. 9 and 27, a first process gas is provided to the substrate 100 to form a first reaction layer 115 on the sidewall 111 of the first insulating layer 110. The first reaction layer 115 has a first thickness T1. The first thickness T1 represents a value measured from the sidewall of the first reaction layer 115 in contact with the first region 131 of the contact hole 130. The first process gas may include a reaction gas and an unreacted gas. The first reaction gas may include HF. For example, the first reaction gas may be formed of only HF gas. An unreacted gas may include nitrogen and/or an inactivated gas (e.g., argon Ar). As shown in the above reaction formula 1, the provided first reaction gas HF responds to the first insulating layer 110 to form the first reaction layer 115 including SiF₄. The unreacted gas maintains or controls a pressure of a process chamber (not shown) including the substrate 100 or is used as a purge gas. The first reaction gas and the unreacted gas may be simultaneously or sequentially provided. The first reaction gas and the unreacted gas may also be repeatedly provided.

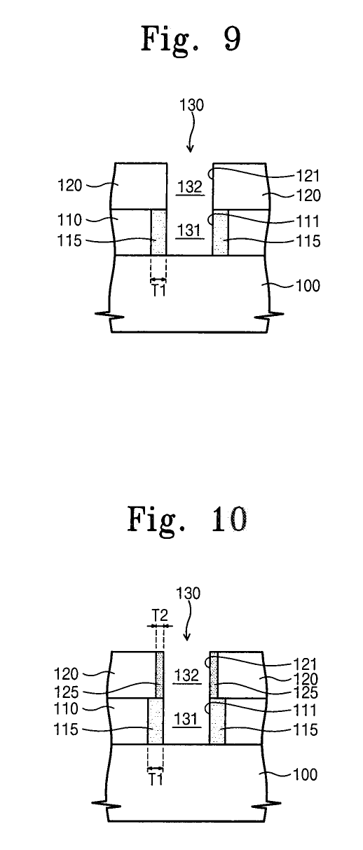

Referring to FIGS. 10 and 27, a second process gas is provided to the substrate 100 to form a second reaction layer 125 on a sidewall of the second insulating layer (S40). The second reaction layer 125 has a second thickness T2. The second thickness T2 represents a value measured from the sidewall of the second reaction layer 115 in contact with the second region 132 of the contact hole 130. The second thickness T2 may be smaller than the first thickness T1. The second process gas may include a second reaction gas and an unreacted gas. The second process gas may include NH₃ and HF and the unreacted gas may include nitrogen and/or an inactivated gas (e.g., argon gas). As shown in inactivated formulas 1, 2 and 3, the provided second reaction gas NH3 and HF respond to the second insulating layer 120 to form the second reaction layer 125 including SiF₄ and/or (NH₄)₂SiF₆. A portion of the second reaction gas may react to the first reaction layer. The unreacted gas maintains or controls a pressure of a process chamber (not shown) including the substrate 100 or is used as a purge gas. The second reaction gas and the unreacted gas may be simultaneously or sequentially provided. The second reaction gas and the unreacted gas may also be repeatedly provided.

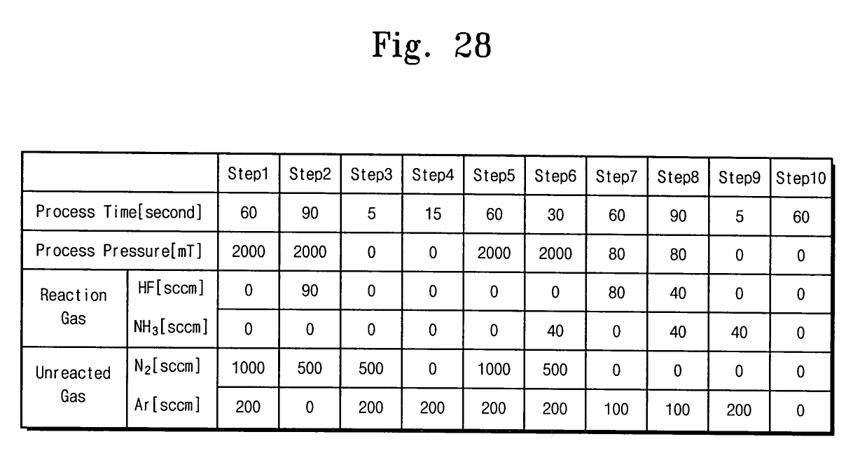

Referring to FIGS. 9, 10 and 28, a step-by-step process for the first reaction layer 115 and the second reaction layer 125 will be described. A process for forming the first and second reaction layers 115 and 125 in an embodiment may include ten step processes.

A first step is a preliminary step for forming the first reaction layer 115, and an unreacted gas is provided to maintain a process pressure of 1500˜2500 mT (for example 200 mT). A second step is a step for forming the first reaction layer 115, and HF of the first reaction gas of 50˜130 sccm (for example 90 sccm) and N2 of an unreacted gas of 300˜800 sccm (for example 500 sccm) are provided to the substrate 100 in the condition that a process pressure is maintained at 1500˜2500 mT (for example 2000 mT). The provided HF is reacted to a sidewall 111 of the first insulating layer to form the first reaction layer 115 including SiF₄. A third step and a fourth step are steps of purging a process chamber and an unreacted gas may be provided and a process pressure is maintained at 0 mT. A fifth step is a preliminary step for forming the second reaction layer 125 and an unreacted gas is provided to maintain a process pressure at 1500˜2500 mT (for example 2000 mT). Sixth to eighth steps are steps for forming the second reaction layer 125, and HF and NH₃ of the second reaction gas and an unreacted gas are provided to the substrate 100. In a case of the second reaction gas, HF and NH₃ of respective 50˜120 sccm, 20˜60 sccm (for example 80 sccm, 40 sccm) are separately provided in the sixth and seventh steps, and HF and NH₃ of respective 20˜60 sccm (for example 40 sccm) are simultaneously provided in the eight step. In a case of the unreacted gas, N2 and Ar of respective 300˜800 sccm, 50˜200 sccm (for example 500 sccm, 200 sccm) are provided in the sixth step and Ar of 50˜200 sccm (for example 100 sccm) is provided in the seventh and eighth steps. A process pressure is maintained at 1500˜2500 mT (for example 200 mT) in the sixth step and a process pressure is maintained at 50˜120 mT (for example 80 mT) in the seventh and eighth steps. The sixth and seventh steps are omitted in another embodiment. Ninth and tenth steps are steps of purging a process chamber, and an unreacted gas may be provided and a process pressure is maintained at 0 mT. A process of forming the first reaction layer 115 by the first to fourth steps and a process of forming the second reaction layer 125 by the fifth to tenth steps corresponds to an in-situ process. When the first and second reaction layers 115 and 125 are formed, the temperature may be 25˜60° C.

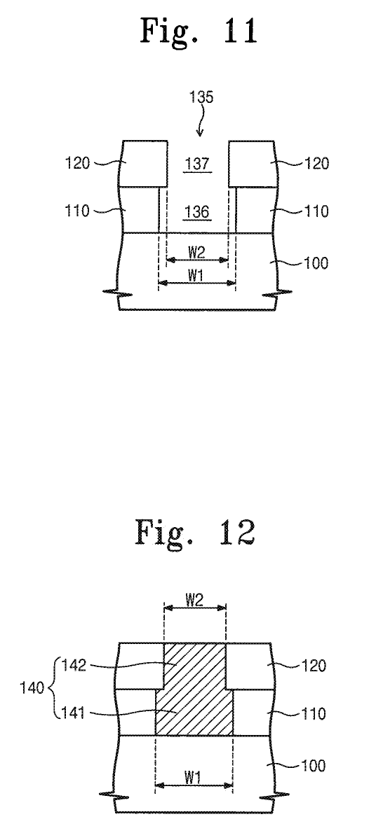

Referring to FIGS. 11 and 27, the first and second reaction layers 115 and 125 are evaporated and removed by heating the substrate 100 to form a enlarged contact hole 135. The heating temperature may be 100˜200° C. The contact hole 135 may include a first region 136 and a second region 137. The first region 136 has a first width W1 and the second region 137 has a second width W2 smaller than the first width W1. The first region 136 is defined by the first insulating layer 110 and the second region 137 is defined by the second insulating layer 120.

Referring to FIGS. 12 and 27, the contact hole 135 is filled with conductive material to form a contact plug 140 (S60). The contact plug 140 may include a first portion 141 and a second portion 152. The first portion 141 corresponds to the first region 136 of the contact hole 135 and has the first width W1. The second portion 142 corresponds to the second region 137 of the contact hole 135 and has the second width W2 smaller than the first width W1.

According to exemplary embodiments of the present invention, after forming a reaction layer on a sidewall of a contact hole, a width of the contact hole may be uniformly enlarged by removing the reaction layer. Alternatively, after forming reaction layers having different thicknesses on a sidewall of a contact hole, the reaction layers are removed to form a contact hole having an upper portion width and a lower portion width which are different from each other. A contact plug formed in the contact hole may also have an upper portion width and a lower portion width which are different from each other. A best suited semiconductor device may be embodied by applying the contact plug to a semiconductor device. For instance, in a case that contact margins of an upper portion and a lower portion are different, an electrical connection that may occur in an upper portion or a lower portion is prevented by forming a contact plug an upper portion and a lower portion of which have different widths according to the contact margins.

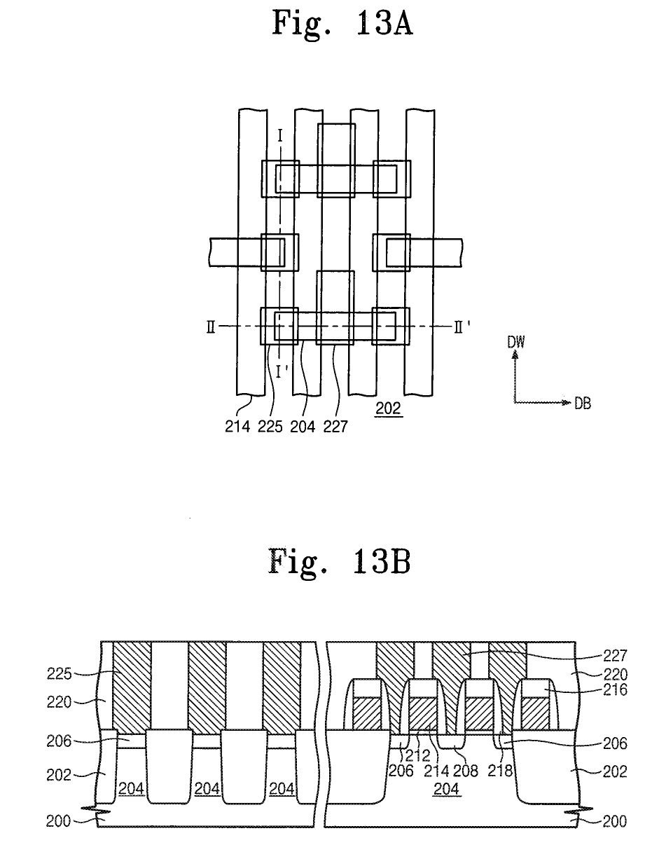

Referring to FIGS. 13A to 19B, a semiconductor device and a method of forming the same in accordance with another embodiment of the present invention are described.

Referring to FIGS. 13A and 13B, a device isolation layer 202 that defines an active region 204 in a substrate 200 is formed. The active region 204 may be arranged along a first direction DW and a second direction DB. The active region 204 may have various shapes and arrangements and is not limited to a shape and an arrangement shown in FIG. 13A. A gate line 214 that extends in the first direction DW is formed on the substrate 200. A gate insulating layer 212 is formed between the active region 204 and the gate line 214, and a capping layer 216 is formed on the gate line 214. Spacers 218 are formed on both sides of the gate line 214. Impurity regions 206 and 208 are formed in the active region 204 adjacent to both sides of the gate line 214. The impurity regions 206 and 208 functions as source/drain regions. A first interlayer insulating layer 220 is formed on the substrate 200 including the gate line 214. Contact pads 225 and 227 that penetrates the first interlayer insulating layer 220 and are in contact with impurity regions 206 and 208 are formed.

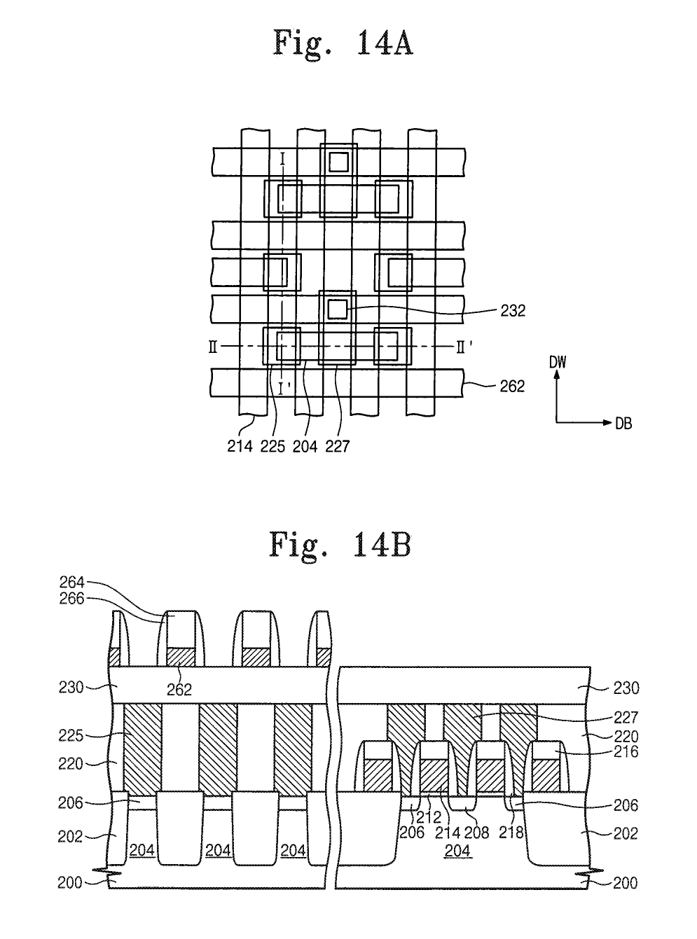

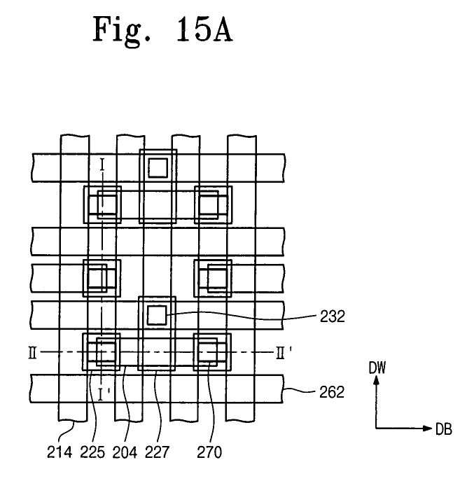

Referring to FIGS. 14A and 14B, a second interlayer insulating layer 230 is formed on the first interlayer insulating layer 220 including the contact pads 225 and 227. The second interlayer insulating layer 230 may be formed of BPSG. A bit line contact 232 that penetrates the second interlayer insulating layer 230 and is in contact with the contact pad 227 is formed. A bit line 262 that extends in the second direction DB is formed on the second interlayer insulating layer 230 including the bit line contact 232. A capping layer 264 is formed on the bit line 262 and spacers 266 are formed on both sidewalls of the bit line 262.

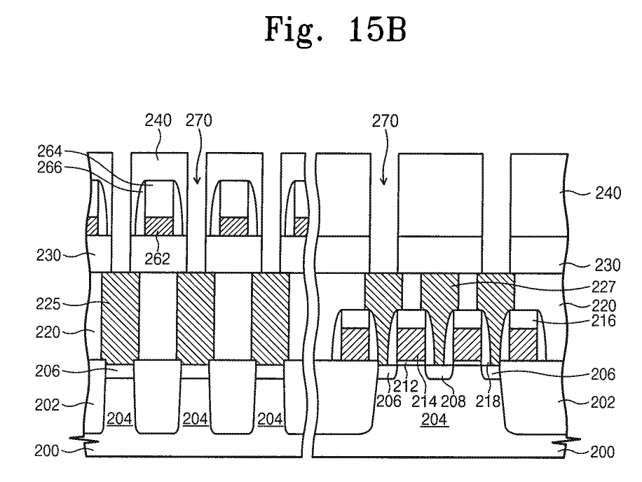

Referring to FIGS. 15A and 15B, a third interlayer insulating layer 240 is formed on the second interlayer insulating layer 230 including the bit line 262. The third interlayer insulating layer 240 may be formed of HDP oxide material or TEOS. The second and third interlayer insulating layers are patterned to form a contact hole 270 exposing the contact pad 225. Sidewalls of the second and third interlayer insulating layers 230 and 240 patterned by the contact hole 270 are exposed.

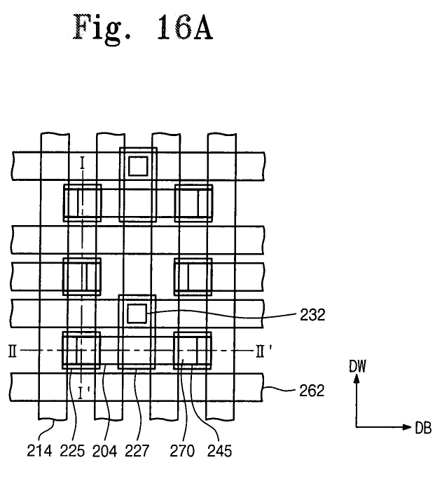

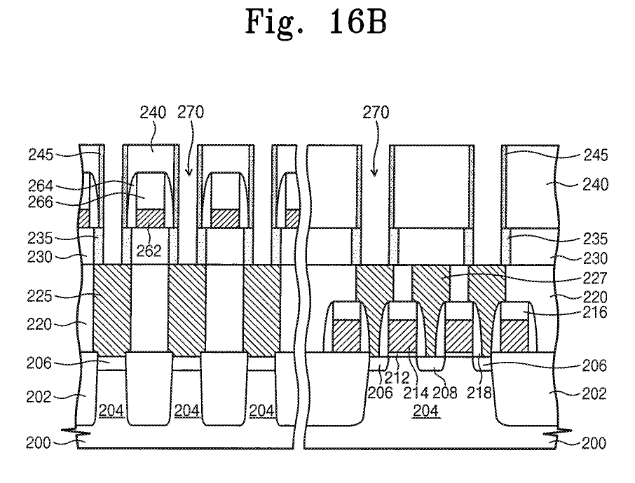

Referring to FIGS. 16A and 16B, a first process gas is provided to the substrate 200 to form a first reaction layer 235 on a sidewall of the second interlayer insulating layer 230 exposed by the contact hole 270. The first process gas may include a first reaction gas and an unreacted gas. The first reaction gas may include HF. For example, the first reaction gas may be formed of only HF gas. An unreacted gas may include nitrogen and/or an inactivated gas (e.g., argon Ar). As shown in the reaction formula 1, a provided first reaction gas HF is reacted to the second interlayer insulating layer 230 to form a first reaction layer 235 including SiF4. The unreacted gas maintains or controls a pressure of a process chamber (not shown) including the substrate 200 or is used as a purge gas. The first reaction gas and the unreacted gas may be simultaneously or sequentially provided. The reaction gas and the unreacted gas may also be repeatedly provided.

A second process gas is provided to the substrate 200 to form a second reaction layer 245 on a sidewall of the third interlayer insulating layer 240 exposed by the contact hole 270. A thickness of the second reaction layer 245 may be smaller than a thickness of the first reaction layer 235. The thicknesses of the first and second reaction layers 235 and 245 represent values measured from the sidewalls of the first and second reaction layer 235 and 245 in contact with the contact hole 270. The second process gas may include a second reaction gas and an unreacted gas. The second process gas may include NH₃ and HF, and the unreacted gas may include nitrogen and/or an inactivated gas (e.g., argon gas). As shown in inactivated formulas 1, 2 and 3, the provided second reaction gas NH3 and HF respond to the third interlayer insulating layer 240 to form the second reaction layer 245 including SiF₄ and/or (NH₄)₂SiF₆. The unreacted gas maintains or controls a pressure of a process chamber (not shown) including the substrate 100 or is used as a purge gas. The second reaction gas and the unreacted gas may be simultaneously or sequentially provided. The second reaction gas and the unreacted gas may also be repeatedly provided.

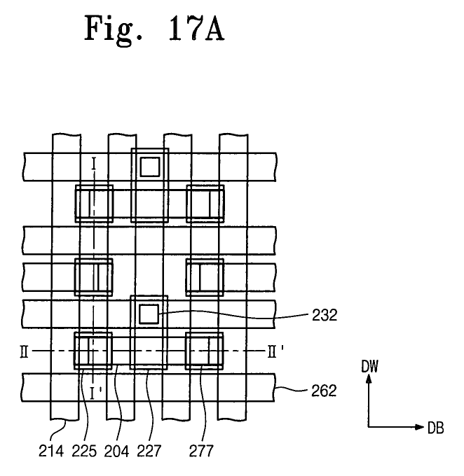

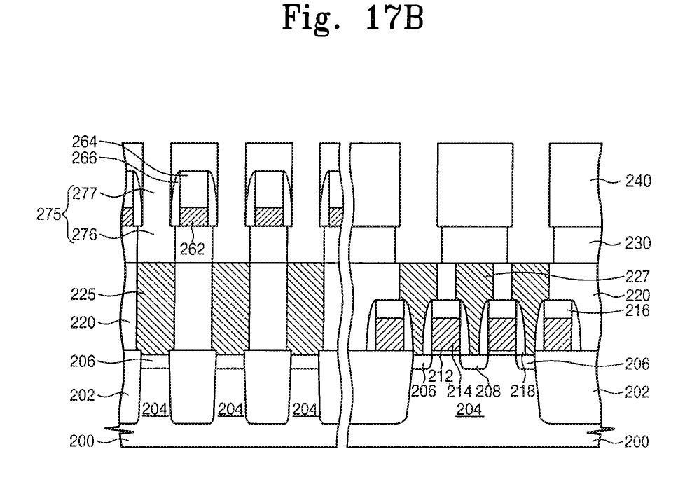

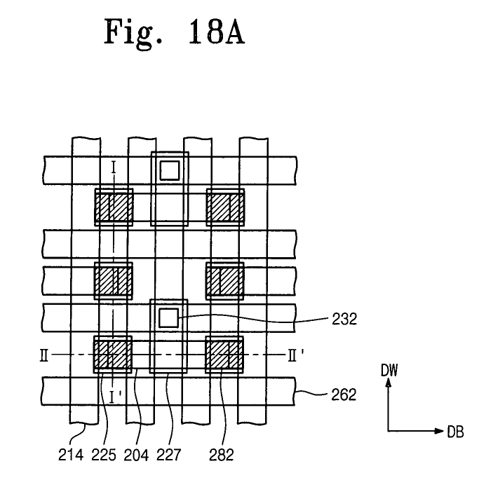

Referring to FIGS. 17A and 17B, the first and second reaction layers 235 and 245 are evaporated and removed by heating the substrate 200 to form a enlarged contact hole 275. The heating temperature may be 100˜200° C. The contact hole 275 may include a first region 276 and a second region 277 which have different widths. The first region 276 may have a width greater than the second region 277. The first region 276 is defined by the second interlayer insulating layer 230 and the second region 137 is defined by the third interlayer insulating layer 240.

Since the first and second reaction layers 235 and 245 are removed by heating, problems of an etching process using an etching gas or an etching solution may be prevented. For example, in a case of a wet etching using a hydro fluoric acid solution, the contact pad 225 may be damaged. In a case that an upper surface of the contact pad 225 is a metal silicide, the contact pad 225 may seriously damaged. However, in the embodiments of the present invention, there is no possibility that a lower layer such as the contact pad 225 is damaged. It is very difficult to form a contact hole having a lower portion width and an upper portion width which are different from each other using only an etching process. However, in the embodiments of the present invention, since the widths of the first and second reaction layers 135 and 245 are controlled by controlling a flow rate and a process pressure of the first and second reaction gases, the widths of the first and second regions 276 and 277 of the contact hole may be finely controlled.

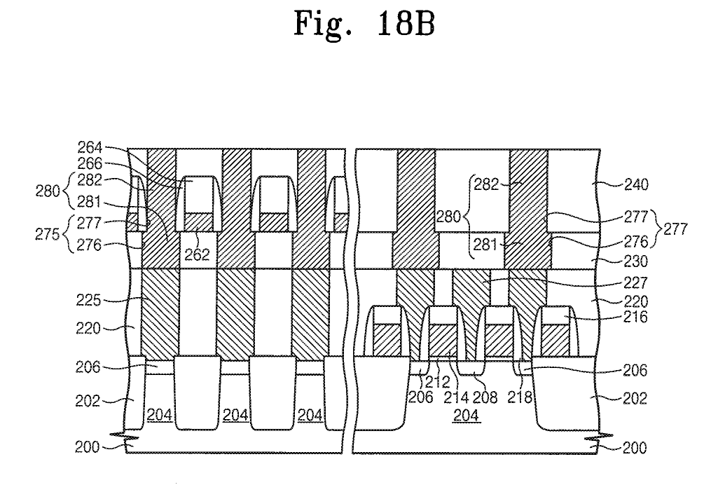

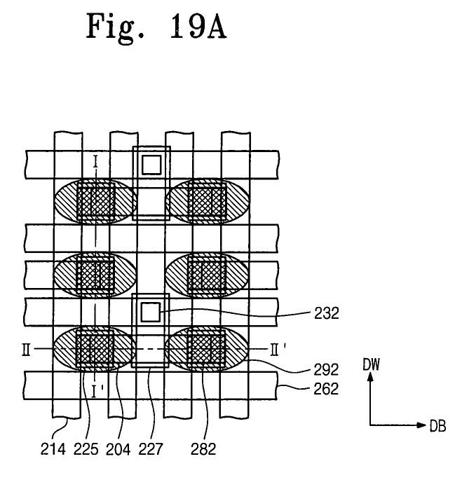

Referring to FIGS. 18A and 18B, the contact hole 275 is filled with conductive material to form a contact plug 280. The contact plug 280 may include a first portion 281 and a second portion 282 which have different widths. The first portion 281 corresponds to the first region 276 of the contact hole 275 and the second portion 282 corresponds to the second region 277 of the contact hole 275. As described above, the contact plug 280 formed in the finally enlarged contact hole 275 is not electrically connected to the adjacent contact pads 225 and 227, and a bit line 262.

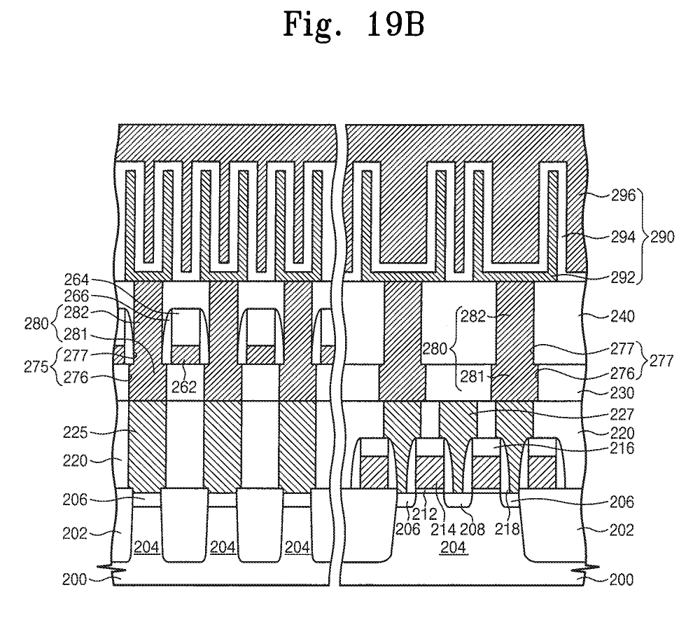

Referring to FIGS. 19A and 19B, a storage electrode 292 is formed on the third interlayer insulating layer 240. The storage electrode 292 is in contact with an upper surface of the contact plug 280. The storage electrode 292 may have a cylinder shape. Alternatively, the storage electrode 292 may have a different shape. A capacitor dielectric layer 294 is formed on a surface of the storage electrode 292 and a plate electrode 296 is formed on the capacitor dielectric layer 294 to cover the storage electrode 292. A capacitor 290 includes the storage electrode 292, the capacitor dielectric layer 294 and the plate electrode 296.

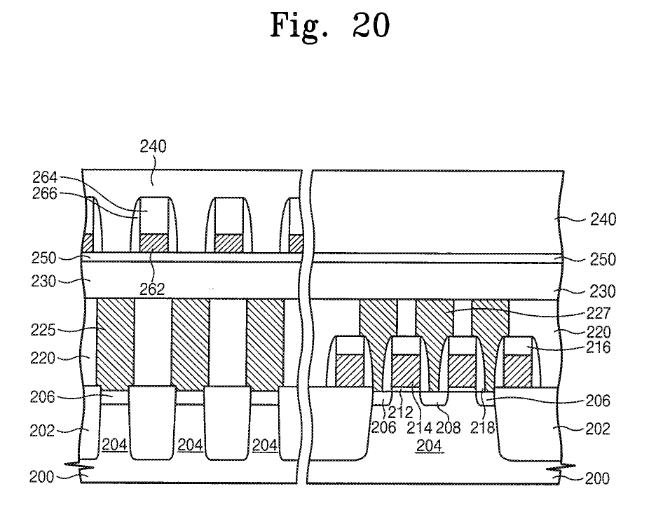

Referring to FIGS. 20 to 25, a semiconductor device and a method of forming the same in accordance with still another embodiment of the present invention are described. Descriptions of overlapped parts with the aforementioned embodiment may be omitted.

Referring to FIG. 20, a fourth interlayer insulating layer 250 is formed between the second interlayer insulating layer 230 and the third interlayer insulating layer 240. The second and fourth interlayer insulating layers 230 and 250 are sequentially stacked on the first interlayer insulating layer 220 including the contact pads 225 and 227. The second interlayer insulating layer 230 may be formed of BPSG and the fourth interlayer insulating layer 250 may be formed of HDP oxide material or TEOS.

A bit line contact 262 that penetrates the second and fourth interlayer insulating layers 230 and 250 and are in contact with the contact pad 227 is formed. A bit line 262 that extends in the second direction DB is formed on the fourth interlayer insulating layer 250. The bit line 262 is in contact with the bit line contact 232. A capping layer 264 is formed on the bit line 262 and spacers 266 are formed on both sidewalls of the bit line 262.

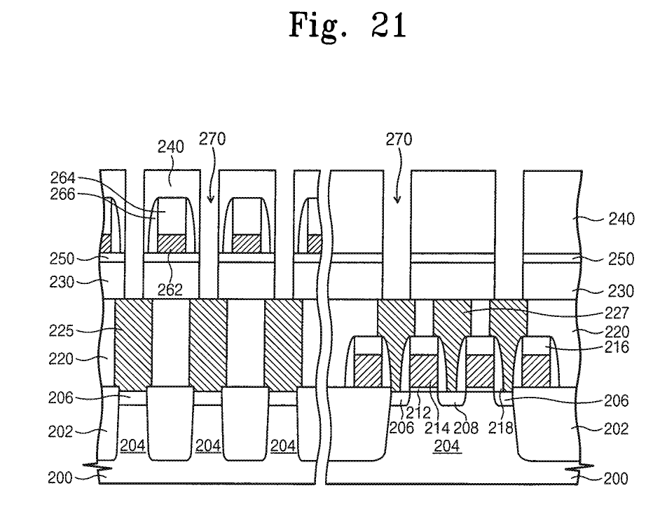

Referring to FIG. 21, the third interlayer insulating layer 240 including the bit line 262 is formed on the fourth interlayer insulating layer 250. The third interlayer insulating layer 240 may be formed of HDP oxide material or TEOS. The third and fourth interlayer insulating layer 240 and 250 may be formed of the same material. The second to fourth interlayer insulating layers 230, 240 and 250 are patterned to form a contact hole 270 that exposes the contact pad 225. Sidewalls of the second to fourth interlayer insulating layers 230, 240 and 250 patterned by the contact hole 270 are exposed.

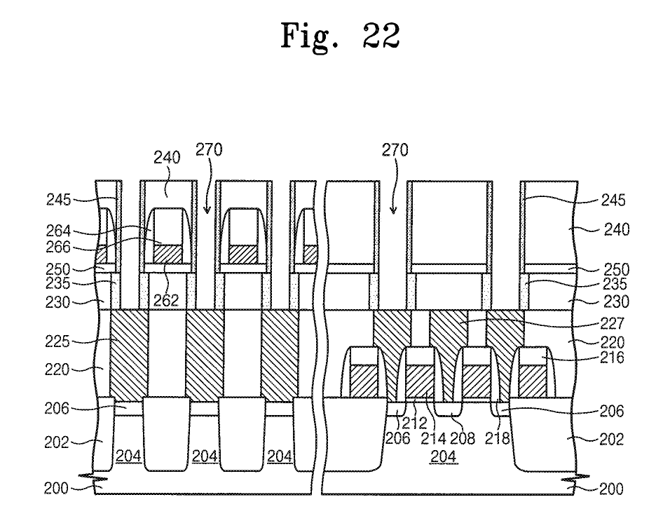

Referring to FIG. 22, a first process gas is provided to the substrate 200 to form a first reaction layer 235 on a sidewall of the second interlayer insulating layer 230 exposed by the contact hole 270. A second process gas is provided to the substrate 200 to form a second reaction layer 245 on sidewalls of the third interlayer insulating layer 240 and the fourth interlayer insulating layer 250 exposed by the contact hole 270. A thickness of the second reaction layer 245 may be smaller than a thickness of the first reaction layer 235. The thicknesses of the first and second reaction layers 235 and 245 represent values measured from the sidewalls of the first and second reaction layer 235 and 245 in contact with the contact hole 270. A process of forming the first and second reaction layers 235 and 245 is the same as the aforementioned embodiment.

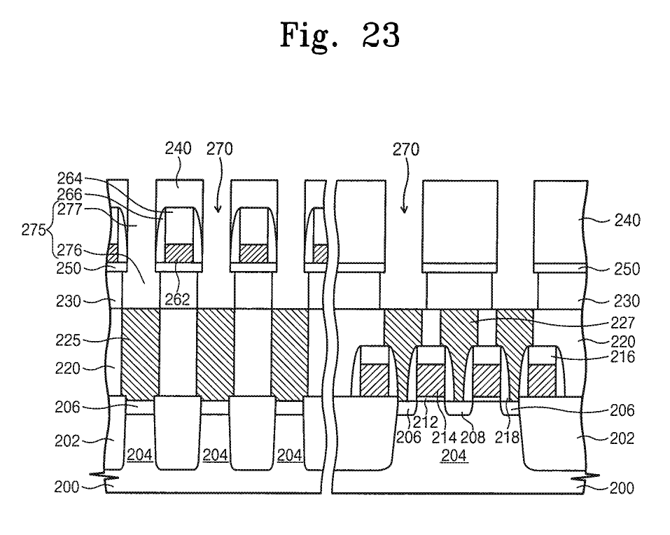

Referring to FIG. 23, the first and second reaction layers 235 and 245 are evaporated and removed by heating the substrate 200 to form a enlarged contact hole 275. The contact hole 275 may include a first region 276 and a second region 277 which have different widths. A width of the first region 276 may be greater than a width of the second region 277. The first region 276 is defined by the second interlayer insulating layer 230 and the second region 277 is defined by the third and fourth interlayer insulating layer 250.

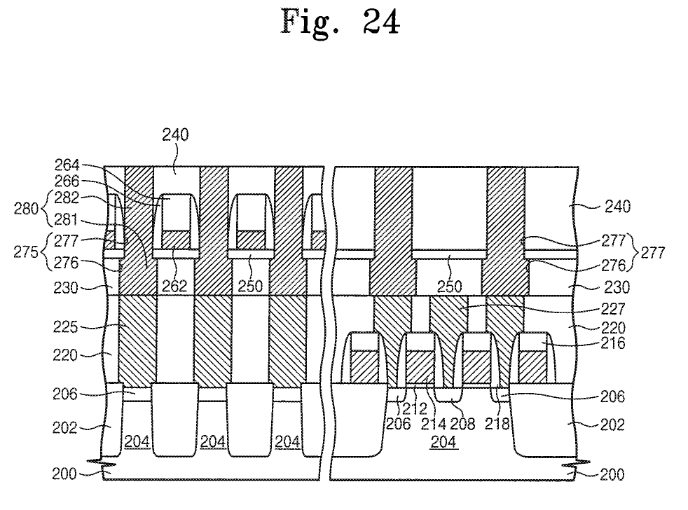

Referring to FIG. 24, the contact hole 275 is filled with conductive material to form contact plug 280. The contact plug 280 may include a first portion 281 and a second portion 282 which have different widths. The first portion 281 corresponds to the first region 276 of the contact hole 275 and the second portion 282 corresponds to the second region 277 of the contact hole 275. As described above, the contact plug 280 formed in the finely enlarged contact hole 275 is not electrically connected to the adjacent 225 and 227, and the bit line 262. In the present embodiment, though the first portion 281 of the contact plug 280 extends under the bit line 250 more than the aforementioned embodiment, the first portion 281 is not electrically connected to the bit line 262 because the fourth interlayer insulating layer 250 is formed under the bit line 262.

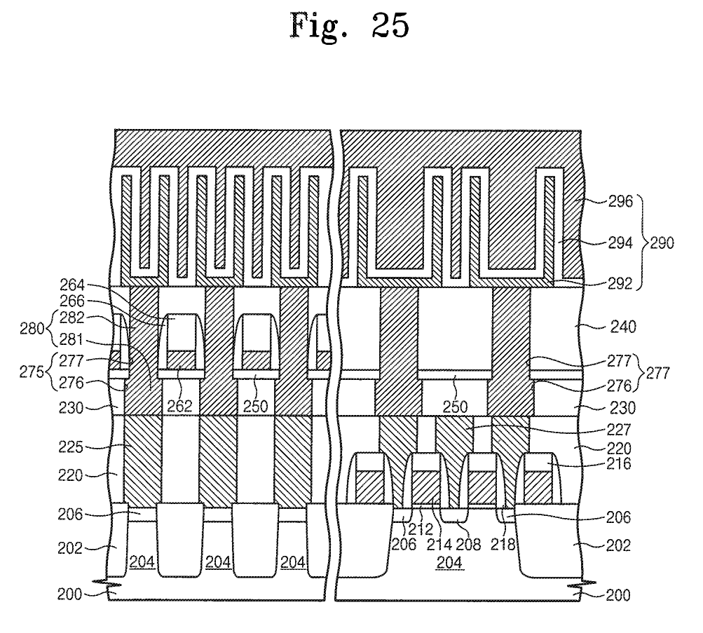

Referring to FIG. 25, a storage electrode 292 is formed on the third interlayer insulating layer 240. The storage electrode 292 is in contact with an upper surface of the contact plug 280. A capacitor dielectric layer 294 is formed on a surface of the storage electrode 292 and a plate electrode 296 is formed on the capacitor dielectric layer 294 to cover the storage electrode 292. The capacitor 290 includes the storage electrode 292, the capacitor dielectric layer 294 and the plate electrode 296.

What is claimed is:

1. A surface treatment method of removing an oxide material on a surface of a substrate, the method comprising:
reacting the oxide material with HF to form a reaction layer; and
heating and removing the reaction layer.

2. The method of claim 1, wherein the oxide material includes BPSG.

3. A surface treatment method of removing a first oxide material and a second oxide material on a surface of a substrate, the method comprising:
reacting the first oxide material with HF to form a first reaction layer;
reacting the second oxide material with HF and NH₃ to form a second reaction layer; and
removing the first and second reaction layers.

4. The method of claim 3, wherein the first oxide material includes BPSG and the second oxide material includes HDP oxide material or TEOS.

5. The method of claim 3, wherein removing the first and second reaction layers includes heating the first and second reaction layers.

6. The method of claim 3, wherein the first oxide material and the second oxide material are disposed in a contact hole formed on the substrate.

7. A method of forming a semiconductor device, comprising:
forming a first oxide layer and a second oxide layer on a substrate;
patterning the first and second oxide layers to form a contact hole that exposes the substrate;
reacting a sidewall of the first oxide layer exposed by the contact hole with HF to form a first reaction layer;
reacting a sidewall of the second oxide layer exposed by the contact hole with NH₃ and HF to form a second reaction layer;
removing the first and second reaction layers to enlarge the contact hole; and
forming a contact plug in the enlarged contact hole.

8. The method of claim 7, wherein the first oxide layer includes BPSG and the second oxide layer includes HDP oxide material or TEOS.

9. The method of claim 7, wherein enlarging the contact hole includes heating and removing the first and second reaction layers.

10. The method of claim 7, wherein the enlarged contact hole includes a first region and a second region that have different widths.

11. The method of claim 10, wherein the first region is defined by the first oxide layer and the second region is defined by the second oxide layer.

12. A method of forming a semiconductor device, comprising:
forming a first interlayer insulating layer including a conductive pad connected to an active region on a substrate including the active region;
forming a second interlayer insulating layer and a third interlayer insulating layer on the first interlayer insulating layer;
patterning the second and third interlayer insulating layers to form a contact hole exposing the conductive pad;
reacting a sidewall of the second interlayer insulating layer exposed by the contact hole with HF to form a first reaction layer;
reacting to a sidewall of the third interlayer insulating layer exposed by the contact hole with NH3 and HF to form a second reaction layer;
removing the first and second reaction layers to enlarge the contact hole; and
forming a contact plug in the enlarged contact hole.

13. The method of claim 12, wherein the second interlayer insulating layer includes BPSG and the third interlayer insulating layer includes HDP oxide material or TEOS.

14. The method of claim 12, wherein enlarging the contact hole includes heating and removing the first and second reaction layers.

15. The method of claim 14, wherein the heating temperature is 100˜200° C.

16. The method of claim 12, wherein the enlarged contact hole includes a first region and a second region that have different widths.

17. The method of claim 16, wherein the first region is defined by the second interlayer insulating layer and the second region is defined by the third interlayer insulating layer.

18. The method of claim 12, wherein forming the second interlayer insulating layer includes forming conductive lines on the second interlayer insulating layer and the contact hole is formed between the conductive lines.

19. The method of claim 18, before forming the conductive lines, further comprising forming a fourth interlayer insulating layer on the second interlayer insulating layer.

20. The method of claim 19, wherein the fourth interlayer insulating layer includes HDP oxide material or TEOS.

21. The method of claim 12, further comprising forming a capacitor on the contact plug.

22. The method of claim 12, wherein in a step of forming the first reaction layer, the HF is provided at a flow rate of 50˜130 sccm.

23. The method of claim 22, wherein in a step of forming the first reaction layer, an unreacted gas including at least one of N₂ and Ar is provided.

24. The method of claim 23, wherein the unreacted gas is provided at a flow rate of 300˜800 sccm and a process pressure is maintained at 1500˜2500 mT.

25. The method of claim 12, wherein forming the second reaction layer comprises providing the HF and the NH3 at a flow rate of 20˜60 sccm, respectively.

26. The method of claim 25, wherein forming the second reaction layer comprises providing an unreacted gas including at least one of N₂ and Ar.

27. The method of claim 26, wherein the unreacted gas is provided at a flow rate of 50˜200 sccm and a process pressure is maintained at 50˜120 mT.

28. The method of claim 12, wherein the first and second reaction layers are formed at temperature of 25˜60° C.

29. A semiconductor device, comprising:
a first oxide layer on a substrate;
a second oxide layer on the first oxide layer; and
a contact plug that penetrates the first and second oxide layers and is connected to the substrate, the contact plug including a first portion and a second portion which have different widths.

30. The device of claim 29, wherein a sidewall of the first portion is in contact with the first oxide layer and a sidewall of the second portion is in contact with the second oxide layer.

31. The device of claim 29, wherein the first portion has a greater width than the second portion.

32. The device of claim 29, wherein the first oxide layer includes BPSG and the second oxide layer includes HDP oxide material or TEOS.

33. A semiconductor device, comprising:
a substrate including an active region;
a first interlayer insulating layer including a conductive pad connected to the active region on the substrate;
a second interlayer insulating layer and a third interlayer insulating layer on the first interlayer insulating layer; and
a contact plug that penetrates the second and third interlayer insulating layers and is connected to the conductive pad, the contact plug including a first portion and a second portion which have different widths.

34. The device of claim 33, wherein a sidewall of the first portion is in contact with the second interlayer insulating layer and a sidewall of the second portion is in contact with the third interlayer insulating layer.

35. The device of claim 33, wherein the first portion has a greater width than the second portion.

36. The device of claim 33, wherein the second interlayer insulating layer includes BPSG and the third interlayer insulating layer includes HDP oxide material or TEOS.

37. The device of claim 33, further comprising conductive lines on the second interlayer insulating layer, wherein the contact plug is disposed between the conductive lines.

38. The device of claim 37, further comprising a fourth interlayer insulating layer disposed between the conductive lines and the second interlayer insulating layer.

39. The device of claim 38, wherein the fourth interlayer insulating layer includes HDP oxide material or TEOS.

40. The device of claim 33, further comprising a capacitor on the contact plug.
